(19) United States
(12) Patent Application Publication
(10) Pub. No.: US 2011/0143527 A1
(43) Pub. Date: Jun. 16, 2011

(54) TECHNIQUES FOR GENERATING UNIFORM ION BEAM

(75) Inventors: Wilhelm P. PLATOW, Salem, MA (US); Neil J. Bassom, Hamilton, MA (US); Peter F. Kurunczi, Cambridge, MA (US); Alexander S. Perel, Danvers, MA (US); Craig R. Chaney, Lanesville, MA (US)

(73) Assignee: VARIAN SEMICONDUCTOR EQUIPMENT ASSOCIATES, INC., Gloucester, MA (US)

(21) Appl. No.: 12/964,357

(22) Filed: Dec. 9, 2010

Related U.S. Application Data
(60) Provisional application No. 61/286,113, filed on Dec. 14, 2009.

(51) Int. Cl. H01L 21/265; H01J 37/317; H01J 37/02

(52) U.S. Cl. 438/515; 250/492.21; 257/E21.334

(57) ABSTRACT

Herein an improved technique for generating uniform ion beam is disclosed. In one particular exemplary embodiment, the technique may be realized as a method for processing a substrate with an ion implanter comprising an ion source. The method may comprise: introducing dopant into an ion source chamber of the ion source, the dopant may comprise molecules containing boron and hydrogen; introducing diluent into the ion source chamber, the diluent containing halogen; ionizing the dopant and the diluent into molecular ions and halogen containing ions, the molecular ions containing boron and hydrogen; extracting the molecular ions and the halogen containing ions from the ions source chamber; and directing the molecular ions toward the substrate, where the halogen containing ions may improve uniformity of the molecular ions extracted from the ion source and extend the lifetime of the ion source.

### PRIORITY

This application claims priority to U.S. Provisional Patent Application Ser. No. 61/286,113, filed on Dec. 14, 2009, entitled “Technique For Generating Uniform Ion Beam.” The entire specification of U.S. Provisional Patent Application Ser. No. 61/286,113 is incorporated herein, by reference.

### FIELD

Present disclosure relates generally to techniques for generating uniform molecular ions beam for substrate processing.

### BACKGROUND

Ion implantation is a process for introducing ions into a substrate. In semiconductor manufacturing, ion implantation may be used to alter electrical or optical properties of target substrate. A precise doping profile in an integrated circuit (IC) substrate and its thin-film structure is often, desired for proper IC performance. To achieve a desired doping profile, one or more ion species may be implanted in different doses and at different energy levels.

Referring to FIG. 1, there is shown a conventional ion implantation system 100, As illustrated in the figure, the ion implantation system 100 may comprise an ion source and a complex series of beam-line components through which an ion beam 10 passes. The ion source may comprise an ion source chamber 102 electrically coupled to a power source 101. The ion source may also comprise an extraction electrode 104 disposed near the ion source chamber 102. As illustrated in the figure, the extraction electrode 104 may include a suppression electrode 104a and a ground electrode 104b. The beam-line components, meanwhile, may include, for example, a mass analyzer 106, a first acceleration or deceleration (A1 or D1) stage 108, a collimator 110, and a second acceleration or deceleration (A2 or D2) stage 112, Much like a series of optical lenses that manipulate a light beam, the beam-line components can filter, focus, and manipulate the ion beam 10. During ion implantation, the ion beam 10 generated in the ion source chamber 102 is extracted by the extraction electrode 104. The ion beam 10 is then manipulated by the beam-line components and, thereafter, directed towards a substrate 114. The substrate 114, meanwhile, is mounted on a platen 116 that can be moved in one or more dimensions (e.g., translate, rotate, and tilt) by an apparatus, sometimes referred to as a “roplat.”

The ion implantation system 100 may also include a number of measurement devices, such as a dose control Faraday cup (not shown), a traveling Faraday cup (not shown), and a setup Faraday cup (not shown). These devices may be used to monitor and control the ion beam conditions. It should be appreciated by those skilled in the art that the entire path traversed by the ion beam 10 is evacuated during ion implantation.

With continued miniaturization of semiconductor devices, there has been an increased demand for ultra-shallow junctions. As such, much effort has been devoted to creating shallower, more abrupt, and better activated source-drain extension (SDE) junctions to meet the needs of modern complementary metal-oxide-semiconductor (CMOS) devices.

In manufacturing ultra-shallow junctions, high-perveance (i.e., low-energy and high-beam-current) ion beams are desirable. For a traditional atomic ion beam (i.e., an ion beam consisting of single-species atomic ions), low beam energy is desired to place dopant ions within a shallow region from the surface of the substrate. In addition, high beam current is desirable to maintain an acceptable throughput during production. However, a low-energy ion beam, suffers from space charge effect as like-charged ions in the ion beam mutually repel each other and cause the ion beam to expand. This effect may limit the magnitude of the beam current that can be transported in a beam-line.

When the like-charged ions are positive ions, the space charge effect can be controlled to some extent by introducing electrons into the ion beam. Negative charges on the electrons counteract the repulsion among the positive ions. Since electrons can be produced when beam ions collide with background gas in the ion implanter, transport efficiency of a low-energy ion beam may be improved by increasing the pressure of background gas. However, this improvement in beam transport efficiency is limited, because, once the background gas pressure becomes high enough, a significant fraction of the ions will undergo charge-exchange interactions, resulting in a loss of beam current.

Compared to atomic ion beams, molecular ion beams (i.e., ion beams comprising charged molecules) may be of a lower perveance. That is, molecular ion beams may be more easily transported at a higher energy and lower beam current. The plurality of atoms (including dopant species) in a molecular ion beam share an overall kinetic energy of the molecular ions according to their respective atomic masses. Therefore, to achieve a shallow implant equivalent to a low-energy atomic ion beam, a molecular ion beam may be transported at a higher energy. Since each, molecular ion may contain several atoms of a dopant species and may be transported as a singly-charged species, the molecular ion beam current required to achieve a desired dopant dose may be smaller than that of an equivalent atomic ion beam. The capability of being transported at higher energies and lower beam, currents makes molecular ion beams less susceptible to space-charge effects and therefore suitable for the formation of ultra-shallow junctions.

It is desirable to generate molecular ions with a standard ion source conventionally used for atomic ion implants. One type of ion sources that have been used in high-current ion implantation equipment are indirectly heated cathode (IHC) ion sources 102. FIG. 2 shows a traditional IHC ion source 102. The ion source 102 comprises the ion source chamber 202 with conductive chamber walls 214. At one end of the ion source chamber 202, there is a cathode 206 having a tungsten filament 204 located therein. The tungsten filament 204 is coupled to a first power supply (not shown). The current supplied from the first power supply may heat the tungsten filament 204 and cause thermionic emission of electrons. A second power supply (not shown) may bias the cathode 206 at a much higher potential than the tungsten filament 204 and cause the electrons emitted from the filament 204 to accelerate toward the cathode 206 and thus heat up the cathode 206. The heated cathode 206 may then emit electrons into the ion source chamber 202. A third power supply (not shown) may bias the chamber walls 214 with respect to the cathode 206 so that the electrons are accelerated at a high energy into the ion source chamber. A source magnet (not shown) may create a magnetic field B inside the ion source chamber 202 to confine the energetic electrons, and a repeller 216 at the other end of the ion source chamber 202 may be biased at a same or similar potential as the cathode 206 to repel the energetic electrons. A dopant source 218 may supply a reactive species into the ion source chamber 202. The energetic electrons may interact with the reactive species to produce a plasma 20 contained desired ions 10. The extraction electrode 104 may then extract the ions 10 from the ion source chamber 202 via the extraction aperture 204 for use in the ion implanter, for example, as illustrated in FIG. 1.

When generated in a conventional ion source such as the IHC ion source 104, the molecular ions may interact with each other and deposits or film may form on the walls 214 of the ion source chamber 102, extraction aperture 204, and/or the extraction electrodes 104. Once formed, the deposits may also delaminate or flake off to obstruct the beam. As a result, a non-uniform beam, as illustrated in FIG. 3, may form. A long narrow or ribbon shaped ion beam extracted through elongated extraction aperture (not shown) of the ion source 102 and or the aperture of the extraction electrode 104 is especially sensitive to the delaminated deposits. This non-uniform beam, if excessive, cannot be corrected by other beam-line components, and ion implantation with such a beam may produce less than ideal semiconductor device. Moreover, reduction in beam current and/or glitching may occur during the implantation process.

In view of the foregoing, it would be desirable to provide techniques for generating more uniform molecular ions beam for substrate processing.

### SUMMARY

An improved technique for generating uniform ion beam, is disclosed. In one particular exemplary embodiment, the technique may be realized as a method for processing a substrate with an ion implanter comprising an ion source. The method may comprise: introducing dopant into an ion source chamber of the ion source, the dopant may comprise molecules containing boron and hydrogen; introducing diluent into the ion source chamber, the diluent containing halogen; ionizing the dopant and the diluent into molecular ions and halogen containing ions, the molecular ions containing boron and hydrogen; extracting the molecular ions and the halogen containing ions from the ions source chamber; and directing the molecular ions toward the substrate, where the halogen containing ions may improve uniformity of the molecular ions extracted from the ion source and extend the lifetime of the ion source.

In accordance with other aspects of this particular exemplary embodiment, the molecules may further contain carbon, and the molecular ions may further contain carbon.

In accordance with further aspects of this particular exemplary embodiment, the dopant may be carborane.

In accordance with additional aspects of this particular exemplary embodiment, the diluent may contain one or more species selected from a group consisting of fluorine (F) and chlorine (Cl).

In accordance with further aspects of this particular exemplary embodiment, the dopant and the diluent may be pre-mixed before entry into the ion source chamber.

In accordance with additional aspects of this particular exemplary embodiment, the dopant and the diluent may be mixed in the ion source chamber.

In accordance with further aspects of this particular exemplary embodiment, the dopant may comprise approximately 40% to 90% of a total species in the ion source chamber.

In accordance with additional aspects of this particular exemplary embodiment, the dopant may comprise approximately 6% to 90% of the total species in the ion source chamber.

In accordance with other aspects of this particular exemplary embodiment, the lifetime of the ion source is greater than the lifetime of another ion source by a factor of about 4 or more, the another ion source ionizing the dopant without ionizing the diluent.

In accordance with another exemplary embodiment, the technique may be realized with an apparatus coupled to an ion source chamber of an ion source. The apparatus may comprise: a diluent source for supplying halogen containing diluent into the ion source chamber, the ion source chamber containing dopant, the dopant comprising boron and hydrogen containing molecules, where the diluent, when ionized, may induce conformal formation of deposits in the ion source to improve uniformity of boron and hydrogen containing molecular ions extracted from the ion source.

In accordance with additional aspects of this particular exemplary embodiment, the molecular dopant may further include carbon.

In accordance with further aspects of this particular exemplary embodiment, the halogen may be chlorine gas.

In accordance with another exemplary embodiment, the technique may be realized with an ion implanter for processing a substrate with uniform, ion beam. The ion implanter may comprise: an ion source including an ion source chamber; a dopant source for introducing dopant into the ion source chamber, the dopant comprising molecules containing boron and hydrogen; a diluent source for introducing diluent into the ion source chamber, the diluent containing chlorine; a platen for supporting the substrate; and a diluent controller configured to introduce a predetermine amount of the diluent into the ion source chamber containing the dopant, where the ion source may be configured to ionize the dopant and the diluent into boron and hydrogen containing molecular ions and halogen containing ions, and where the halogen containing ions may promote conformal formation of deposits in the ion source to improve uniformity of the molecular ions extracted from the ion source.

In other aspects of this particular exemplary embodiment, the molecules may further contain carbon.

In additional aspects of this particular exemplary embodiment, the dopant and the diluent may be pre-mixed before entry into the ion source chamber.

In further additional aspects of this particular exemplary embodiment, the dopant and the diluent may be mixed in the ion source chamber.

In other aspects of this particular exemplary embodiment, the dopant may comprise approximately 40% to 90% of a total species in the ion source chamber.

In further aspects of this particular exemplary embodiment, the dopant may comprise approximately 60% to 90% of the total species in the ion source chamber.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described, herein, and with respect to which the present disclosure may be of significant utility.

### BRIEF DESCRIPTION OF THE DRAWINGS

In order to facilitate a fuller understanding of the present, disclosure, reference is now made to the accompanying drawings, in which like elements are referenced with like numerals. These drawings should not be construed as limiting the present disclosure, but are intended to be exemplary only.

FIG. 1 illustrates a conventional ion implantation system.

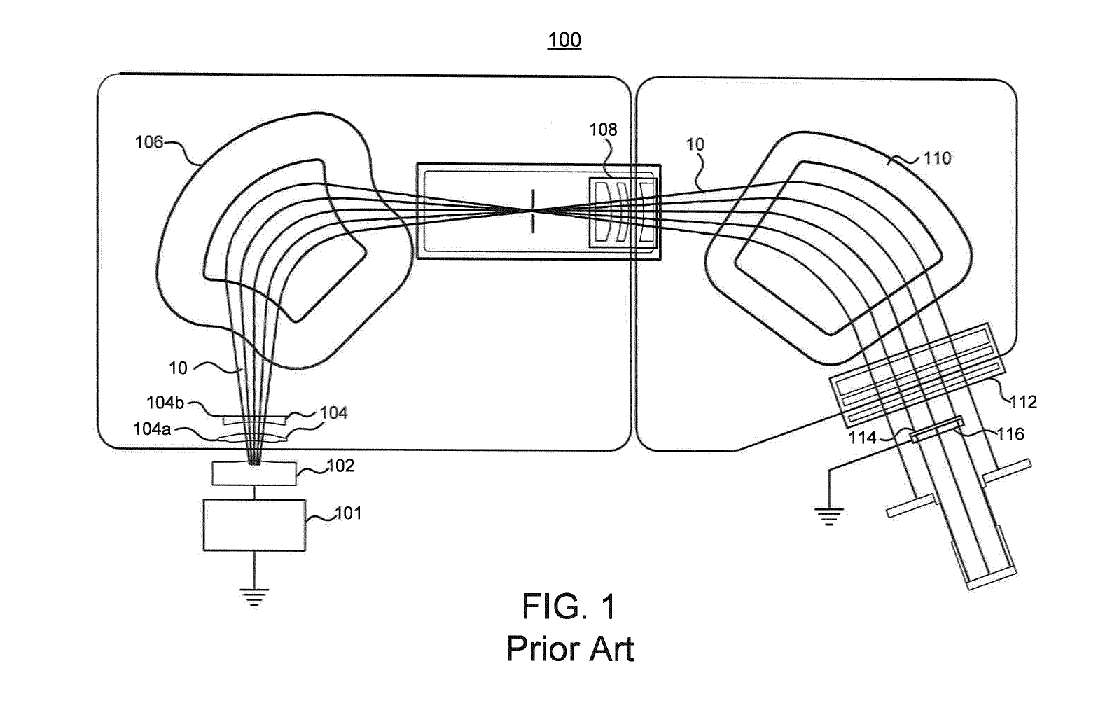

FIG. 2 illustrates a conventional indirectly heated cathode (IHC) ion source included in the ion implantation system shown in FIG. 1.

FIG. 3 illustrates non-uniform beam profile generated from conventional IHC.

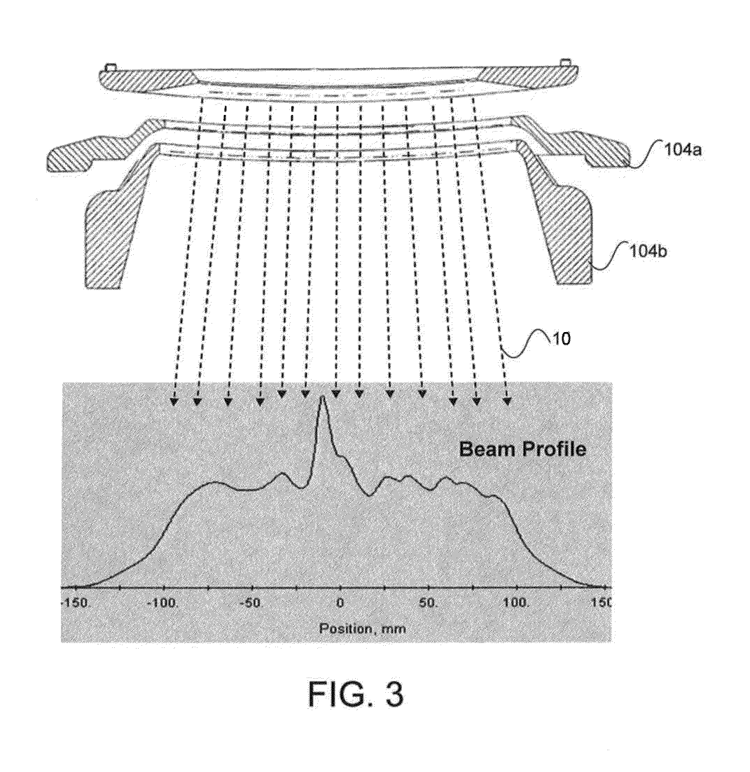

FIG. 4A illustrates an IHC source for generating a uniform ion beam in accordance with one embodiment of the present disclosure.

FIG. 4B illustrates an IHC source for generating a uniform ion beam in accordance with another embodiment of the present disclosure.

FIG. 4C illustrates an IHC source for generating a uniform ion beam in accordance with yet another embodiment of the present disclosure.

### DETAILED DESCRIPTION

Embodiments of the present disclosure may generate uniform ion beam. For purposes of clarity and simplicity, the present disclosure may focus on a technique for generating uniform ion beam in IHC source in a high current, ribbon beam, ion implantation system. Those of ordinary skill in the art will recognize that the present disclosure, however, is not limited to a particular ion source or a particular ion implantation system. The present, disclosure may be equally applicable to other types of ion source including, for example, Bernas source or RF plasma source, in other types of ion implantation systems including, for example, multiple wafer (e.g. batch), spot beam ion implantation system or plasma based ion implantation system. In addition, other the present disclosure may be equally applicable to other plasma based or ion based processing systems.

Further, the present disclosure, for the purposes of clarity and simplicity, may focus on technique for generating uniform carborane molecular ion beam. However, those of ordinary skill in the art will recognize that the present disclosure may be equally applicable to technique for generating other types of uniform molecular ion beam or even atomic ion beam.

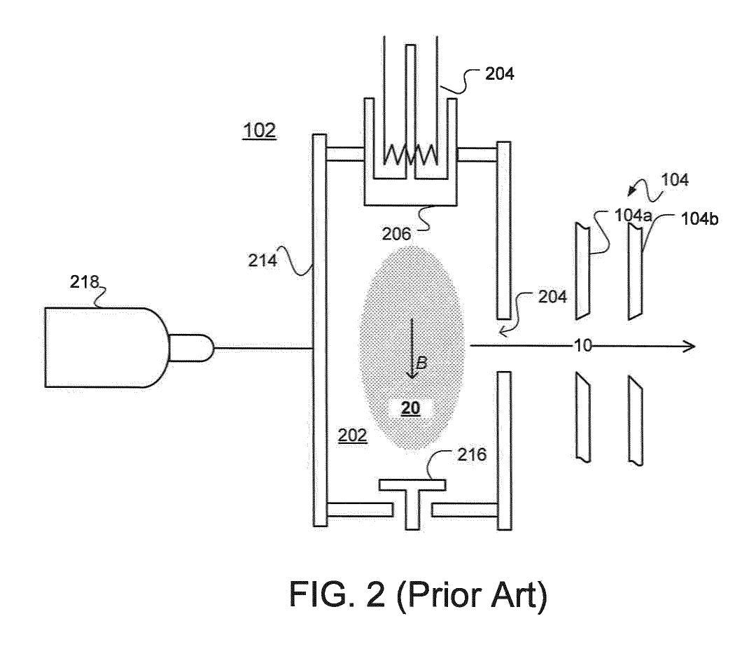

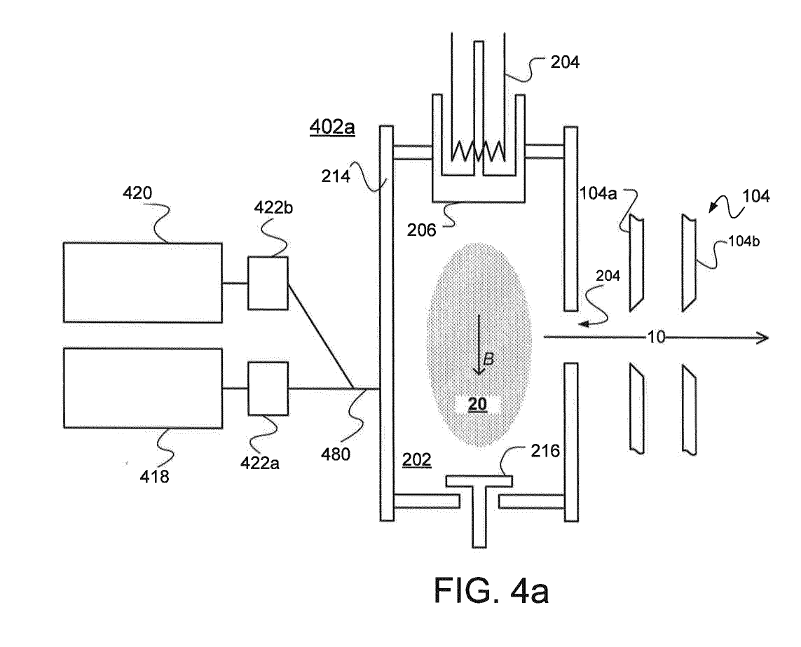

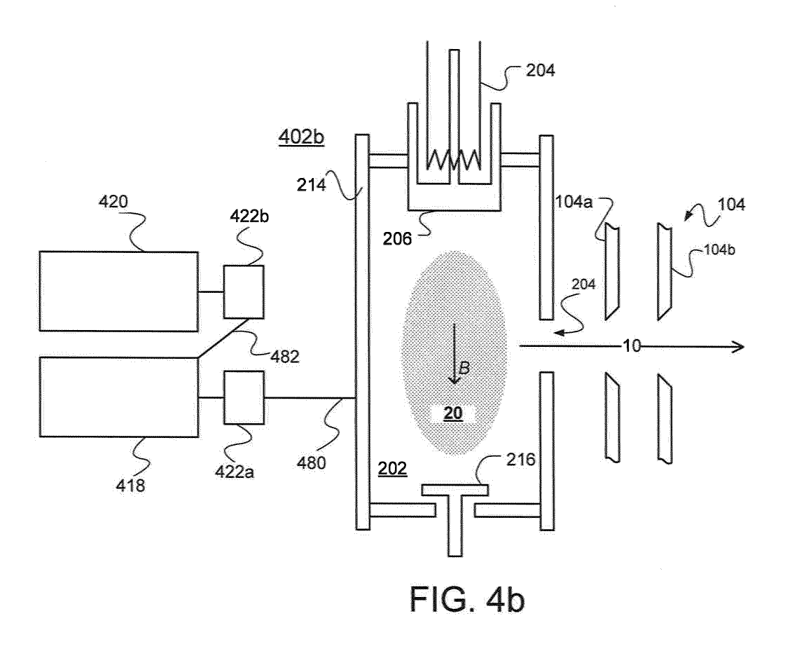

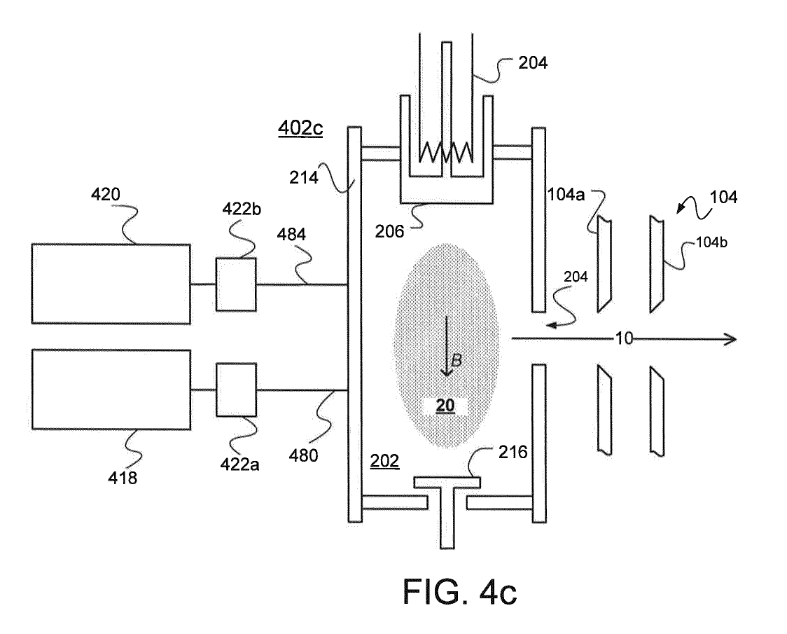

Referring to FIG. 4a-4c, there are shown several exemplary ion sources for generating a uniform molecular ion beam according to embodiments of the present disclosure. It should be appreciated by those skilled in the art that many of the components in FIG. 2 are incorporated into FIG. 4a-4c. As such, many of the components in FIG. 4a-4c should be understood in relation, to the components in FIG. 2.

The ion source 402a-402c may comprise, among others, the ion source chamber 202. The ion source chamber 202 may be coupled, to one or more dopant sources 418 and one or more diluent sources 420. Although the ion source chamber 202 may be coupled to additional dopant and diluent sources, one dopant source 418 and one diluent source 420 are shown and described for the purposes of clarity and simplicity.

In the present disclosure, the dopant and the diluent may preferably be in gas or vapor form when introduced into the ion source chamber 202. Accordingly, the dopant and the diluent in the corresponding sources 418 and 420 may preferably be in the form of gas or vapor. However, those of ordinary skill in the art will recognize that some dopant and/or diluent may be in solid or liquid form, or therebetween. If in solid/liquid form, a vaporizer (not shown) may be disposed near the dopant source 418 and/or the diluent source 420, and the vaporizer may convert the solid/liquid dopant and/or diluent into gas. Herein, the term “gas” or “gaseous” may also include vapor.

From the dopant source 418, the dopant may be introduced, preferably in gaseous state, into the ion source chamber 202. Meanwhile, the diluent may be introduced, preferably is gaseous stage, into the ion source chamber 202 to dilute or mixed with the dopant in the ion source chamber 202. One or more controllers 422a and 422b may be provided to control the amount of dopant and/or diluent introduced into the ion source chamber 202.

In one embodiment, as depicted in FIG. 4a, the dopant and the diluent may be contained in separate sources 418 and 420. However, the dopant and the diluent may be pre-mixed in a first conduit 430 and provided into the ion source chamber 202 together. In another embodiment, as depicted in FIG. 4b, the diluent may be provided into the dopant source 418 via a second conduit 482, or vice versa, and provided into the ion source chamber 202 together. In an embodiment that is not shown, a single source containing a mixture of dopant and diluent may provide them into the ion source chamber. Yet in another embodiment, as depicted in FIG. 4c, the dopant and the diluent may also be provided into the ion source chamber 202 via separate conduits 480 and 484. In this embodiment, the dopant and the diluent may be provided separately, but mixed in the ion source chamber 202.

In several embodiments of the present disclosure, the dopant may have suitable chemical composition that allows production of desired molecular ions. The dopant may preferably have a relatively high molecular weight which results in formation of molecular ions with relatively high molecular weight. The dopant may also preferably have a desired decomposition temperature. In one embodiment, the dopant may foe diborane (B₂H₆) containing boron and hydrogen species. Other boron-containing dopants, in other embodiments, may be those represented by a general formula XBY, wherein B represents boron. In some cases, X and/or Y may represent single element (e.g., X═C (i.e., carbon), Y═H (i.e., hydrogen)); and, in other cases, X and/or Y may represent more than one element (e.g., X═NH₄, NH₃, CH₃), The other dopants may also be represented by another general formula XₐB_{b}Y_{c}, wherein a≧0, b>0, and c>0. In one embodiment, the dopant may be decaborane (B₁₀H₁₂); where Y═H, and a=0, b=10, and c=12. In the preferred embodiment, the dopant may be carborane (C₂B₁₀H₁₂); where X═C and Y═H, and a=2, b=10, and c-=b 12.

In the present embodiment, the diluent may be halogen or halogen containing substance. If carborane is introduced into the ion source chamber 202 as the dopant, the diluent may preferably be chlorine gas or chlorine containing substance (e.g. Cl₂ or CCl₄). However, other halogen or halogen containing substance, including fluorine gas (F₂) and other fluorine containing substance, may also be used.

It is found that introducing halogen or halogen containing substance, especially Cl₂, into the ion source chamber 202 ionizing molecular dopant may provide several advantages. First, less amount deposits may form on the ion source during ionization of the molecular dopant. For example, less amount of deposits may form on the wall of the ion source chamber, the extraction aperture, and the extraction electrodes. In order to analyze the extent of the advantage, several experiments were performed. In one experiment, carborane was ionized without any diluent for a predetermined period of time. In another experiment, a mixture of carborane and Cl₂ was ionized for same period of time. In the former experiment, approximately 17 mg of deposits or film was formed in the ion source. In the latter, however, approximately 6 mg of the film was formed. Accordingly, introducing the diluent into the ion source and ionizing both the dopant and the diluent may reduce the deposits by a factor of 3 or more.

Second, more uniform molecular ion beam may be extracted from the ion source. Without intending to be bound by a particular theory, it is believed that ionizing the mixture, of the dopant (e.g. carborane) and diluent (e.g. Cl₂) resulted, in formation of more con formal deposits or film, the deposits or film that is more stable structurally and/or chemically. It is believed that such deposits or film is less likely to delaminate to obstruct the ion beam resulting in more uniform molecular ion beam.

In addition, more uniform molecular ion beam may be produced for longer period of time. In one experiment, the ion source without the diluent gas was able to ionize and output, uniform carborane ions for about 7 hours. Thereafter, additional uniform ion beam could not be extracted without cleaning and removing the deposits. The ion source ionizing the mixture of the carborane and halogen containing diluent, however, was able to emit uniform carborane ions for about 26 hours. Comparing the results, it is clear that an ion source ionizing the molecular dopant and the diluent may achieve better uniformity for longer period of time, by a factor of 4 or more.

Third, the performance of the ion source may improve. In addition to inducing less uniform beam, deposits formed on the cathode, the repeller electrode, and/or extraction electrodes may result in less stable molecular ion beam. This less stable ion beam may cause beam, current drifts and, in some cases, a higher frequency of glitches, both of which may be critical metrics towards the performance of an ion source.

Fourth, the lifetime of the ion source may be extended. As those of ordinary skill in the art can appreciate, it is desirable to operate the ion source for extended periods of time without the need for maintenance or repair. The lifetime of the ion source or mean time between failures (MTBF) is one performance criteria of the ion source and an important metric for the performance of an ion implanter system.

As noted above, the ion source may fail if excessive amount of deposits are formed or accumulated during extended use of the ion implanter system. If excessively accumulated on the cathode, the deposits tend to reduce a thermionic, emission rate of source ions from cathode surfaces. Moreover, if the film formed in the ion source is electrically conductive, the film may induce short circuit between the cathode and the ion source chamber. This short circuit may prevent formation of plasma within the ion source chamber. As a result, the entire source may have to be replaced or rebuilt. By ionizing both the dopant, such as carborane, and the diluent, such as halogen gas or halogen containing substance (e.g. Cl₂), the lifetime of the ion source or mean time between failures (MTBF) may increase drastically.

In addition to improving performance and lifetime of ion sources in ion implantation systems, the presently disclosed technique for using diluent during ionization of the dopant may have further advantages. For example, greater efficiency in the use of an ion source may be achieved because excessive time and costs due to ineffective, inefficient, and redundant steps associated with traditional ion implantation techniques may be reduced and/or eliminated using the improved diluent technique of the present disclosure.

Thus, embodiments of the present disclosure may provide improved performance and extended lifetime of an ion source in ion implantation systems using dilution to expand the application traditional ion implantation methods and systems.

It should be appreciated that while embodiments of the present disclosure are directed to introducing one or more diluent gases for improving performance and lifetime of ion sources in traditional beam-line ion implantation systems, other implementations may be provided as well. Indeed, other various embodiments of and modifications to the present disclosure, in addition to those described herein, will be apparent to those of ordinary skill in the art from the foregoing description and accompanying drawings. For example, the technique may also apply to plasma-based ion implantation systems including glow discharge plasma doping (GD-PLAD) or radio frequency plasma doping (RF-PLAD) systems. Other various implementations may also apply. Thus, such other embodiments and modifications are intended to fall within the scope of the present disclosure. Further, although the present disclosure has been described, herein in the context of a particular implementation in a particular environment for a particular purpose, those of ordinary skill in the art will recognize that, its usefulness is not limited thereto and that, the present disclosure may be beneficially implemented in any number of environments for any number of purposes. Accordingly, the claims set forth below should be construed in view of the full breadth and spirit of the present disclosure as described herein.

What is claimed is:

1. A method for: processing a substrate with an ion implanter comprising an ion source, the method comprising:
introducing dopant into an ion source chamber of the ion source, the dopant comprising molecules containing boron and hydrogen;
introducing diluent into the ion source chamber, the diluent containing halogen;
ionizing the dopant and the diluent into molecular ions and halogen containing ions, the molecular ions containing boron and hydrogen;
extracting the molecular ions and the halogen containing ions from the ions source chamber; and
directing the molecular ions toward the substrate, wherein the halogen containing ions improve uniformity of the molecular ions extracted from the ion source and extend the lifetime of the ion source.

2. The method of claim 1, wherein the molecules further contain carbon, and wherein the molecular ions further contain carbon.

3. The method of claim 1, wherein the dopant is carborane.

4. The method of claim 1, wherein the diluent contains one or more species selected from a group consisting of flourine (F) and chlorine (Cl).

5. The method of claim 4, wherein the dopant, and the diluent are pre-mixed before entry into the ion source chamber.

6. The method of claim 4, wherein the dopant and the diluent are mixed in the ion source chamber.

7. The method of claim 6, the dopant comprises approximately 40% to 90% of a total species in the ion source chamber.

8. The method of claim 7, wherein the dopant comprises approximately 60% to 90% of the total species in the ion source chamber.

9. The method of claim 4, wherein the lifetime of the ion source is greater than the lifetime of another ion source by a factor of about 4 or more, the another ion source ionizing the dopant without ionizing the diluent.

10. An apparatus coupled to an ion source chamber of an ion source, the apparatus comprising:
a diluent source for supplying halogen containing diluent into the ion source chamber, the ion source chamber containing dopant, the dopant comprising boron and hydrogen containing molecules, wherein the diluent, when ionized, induces conformal formation of deposits in the ion source to improve uniformity of boron and hydrogen containing molecular ions extracted from the ion source.

11. The apparatus of claim 10, wherein the molecular dopant further includes carbon.

12. The apparatus of claim 10, wherein the halogen is chlorine gas.

13. An ion implanter for processing a substrate with uniform ion beam, the ion implanter comprising:
an ion source including an ion source chamber;
a dopant source for introducing dopant into the ion source chamber, the dopant comprising molecules containing boron and hydrogen;
a diluent source for introducing diluent into the ion source chamber, the diluent containing chlorine;
a platen for supporting the substrate; and
a diluent controller configured to introduce a predetermine amount of the diluent into the ion source chamber containing the dopant, wherein the ion source is configured to ionize the dopant and the diluent into boron and hydrogen containing molecular ions and halogen containing ions, and wherein the halogen containing ions promotes conformal formation of deposits in the ion source to improve uniformity of the molecular ions extracted from the ion source.

14. The ion implanter of claim 13, wherein the molecules further contain carbon.

15. The ion implanter of claim 13, wherein the dopant and the diluent are pre-mixed before entry into the ion source chamber.

16. The method of claim 14, wherein the dopant and the diluent are mixed in the ion source chamber.

17. The method of claim 16, the dopant comprises approximately 40% to 90% of a total species in the ion source chamber.

18. The method of claim 17, wherein the dopant comprises approximately 60% to 90% of the total species in the ion source chamber.
